(19) United States
(12) Patent Application Publication
(10) Pub. No.: US 2014/0284654 A1
(43) Pub. Date: Sep. 25, 2014

(54) SEMICONDUCTOR LIGHT EMITTING DEVICE

(71) Applicant: Kabushiki Kaisha Toshiba, Minato-ku (JP)

(72) Inventors: Kazuhiro AKIYAMA, Kanagawa-ken (JP); Shuji Itonaga, Kanagawa-ken (JP)

(73) Assignee: Kabushiki Kaisha Toshiba, Minato-ku (JP)

(21) Appl. No.: 14/020,281

(22) Filed: Sep. 6, 2013

(30) Foreign Application Priority Data
Mar. 25, 2013 (JP) 2013-062988

(51) Int. Cl. H01L 33/56

(52) U.S. Cl. CPC H01L 33/56
USPC 257/100

(57) ABSTRACT

According to one embodiment, a semiconductor light emitting device includes a semiconductor film, an electrode, a passivation film, a sealing resin body, and an intermediate film. The semiconductor film contains a Group III nitride semiconductor. The electrode is connected to a first surface of the semiconductor film. The passivation film covers an end surface of the semiconductor film and the first surface. The sealing resin body covers the first surface and a side surface of the electrode to leave a second surface of the semiconductor film exposed. The intermediate film is provided between the passivation film and the sealing resin body. The absolute value of the difference between an internal stress of the intermediate film and that of the sealing resin body is less than the absolute value of the difference between an internal stress of the passivation film and that of the sealing resin body.

### CROSS-REFERENCE TO RELATED APPLICATIONS

This application is based upon and claims the benefit of priority from Japanese Patent Application No.2013-062988, filed on Mar. 25, 2013; the entire contents of which are incorporated herein by reference.

### FIELD

Embodiments described herein relate generally to a semiconductor light emitting device.

### BACKGROUND

In recent years, LEDs (Light Emitting Diodes) that use Group III nitride semiconductors have been developed. Such an LED is manufactured by, for example, forming a stacked body made of semiconductor layers such as a gallium nitride layer (GaN layer), etc., on a crystal growth substrate, covering the stacked body with a passivation film, burying the stacked body in a resin body, subsequently removing the crystal growth substrate, and forming a fluorescer layer.

### BRIEF DESCRIPTION OF THE DRAWINGS

FIG. 1 is a cross-sectional view showing a semiconductor light emitting device according to a first embodiment;

FIGS. 2A to 2D are cross-sectional views of processes, showing a method for manufacturing the semiconductor light emitting device according to the first embodiment;

FIGS. 3A to 3D are cross-sectional views of processes, showing the method for manufacturing the semiconductor light emitting device according to the first embodiment;

FIG. 4 is a cross-sectional view showing an intermediate film of a semiconductor light emitting device according to a second embodiment; and

FIG. 5 is a cross-sectional view showing an intermediate film of a semiconductor light emitting device according to a third embodiment.

### DETAILED DESCRIPTION

According to one embodiment, a semiconductor light emitting device includes a semiconductor film, an electrode, a passivation film, a sealing resin body, and an intermediate film. The semiconductor film contains a Group III nitride semiconductor. The electrode is connected to a first surface of the semiconductor film. The passivation film covers an end surface of the semiconductor film and a region of the first surface other than a region contacting the electrode. The sealing resin body covers the first surface and a side surface of the electrode to leave a second surface of the semiconductor film exposed. The intermediate film is provided between the passivation film and the sealing resin body. The absolute value of the difference between an internal stress of the intermediate film and that of the sealing resin body is less than the absolute value of the difference between an internal stress of the passivation film and that of the sealing resin body.

Embodiments of the invention will now be described with reference to the drawings.

First, a first embodiment will be described.

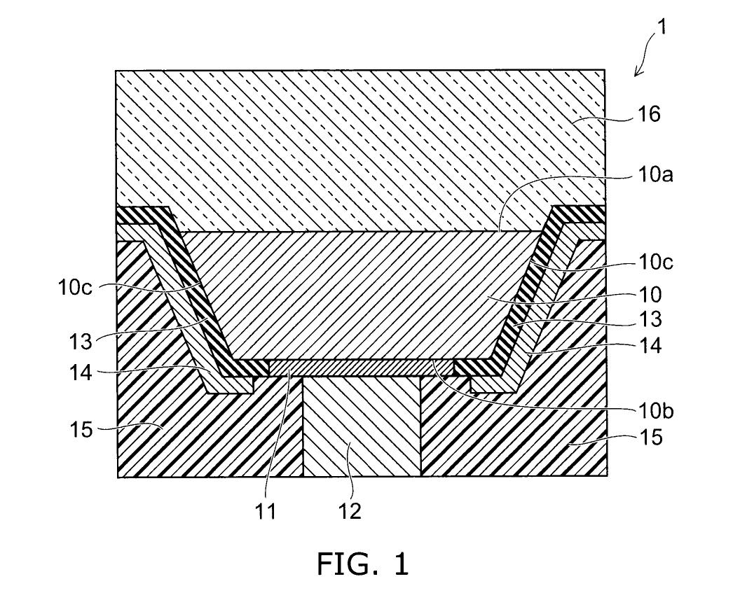

FIG. 1 is a cross-sectional view showing a semiconductor light emitting device according to the embodiment.

As shown in FIG. 1, a semiconductor film 10 is provided in the semiconductor light emitting device 1 according to the embodiment. The semiconductor film 10 is a semiconductor film including a Group III nitride semiconductor, e.g., gallium nitride (GaN), in which multiple layers including a light emitting layer (not shown) are stacked. An upper surface 10a of the semiconductor film 10 is the surface where light is emitted and is flat. A lower surface 10b of the semiconductor film 10 is partitioned into two regions by a stepped portion (not shown); and each of the regions is flat. In FIG. 1, only one region of the lower surface 10b partitioned by the stepped portion is shown; and the other region is not shown because the other region is positioned frontward of the page surface. An end surface 10c of the semiconductor film 10 is tilted at an angle determined by the crystal orientation of the semiconductor film 10.

A re-interconnect layer 11 made of, for example, copper (Cu) is provided on the lower surface 10b of the semiconductor film 10 and is connected to a region of a portion of the semiconductor film 10. Also, an electrode 12 made of, for example, copper is provided on the lower surface of the re-interconnect layer 11 and is connected to the re-interconnect layer 11. In the semiconductor light emitting device 1, two sets of a set that is made of the re-interconnect layer 11 and the electrode 12 are provided as a p-side electrode and an n-side electrode. The sets are insulated from each other and are connected respectively to the two regions of the lower surface of the semiconductor film 10 that are partitioned by the stepped portion. However, only one set of the re-interconnect layer 11 and the electrode 12 is shown in FIG. 1.

A passivation film 13 is provided to cover the lower surface 10b and the end surface 10c of the semiconductor film 10. The passivation film 13 is made of an insulating material and is made of, for example, silicon oxide (SiO₂). The passivation film 13 is not provided on the region of the lower surface 10b of the semiconductor film 10 where the re-interconnect layer 11 is connected and therefore is not interposed between the semiconductor film 10 and the re-interconnect layer 11. Also, the passivation film 13 extends along the end surface 10c of the semiconductor film 10; and an end portion of the passivation film 13 extends beyond the upper surface 10a of the semiconductor film 10 to a position that is higher than the upper surface 10a.

An intermediate film 14 is provided to cover the passivation film 13. The material of the intermediate film 14 is not particularly limited; and the material of the intermediate film 14 may be an insulating film made of an inorganic material, an organic material, etc., or may be a conductive film made of a metal. However, in the case where the intermediate film 14 is a conductive film, the intermediate film 14 is not disposed to be connected to the re-interconnect layer 11 and the electrode 12. For example, a metal film made of chrome (Cr), nickel (Ni), titanium (Ti), etc., may be used as the intermediate film 14. In such a case, the intermediate film 14 functions as a reflective film that reflects, toward the upper surface 10a, the light that is emitted downward or sideward from the light emitting layer of the semiconductor film 10. The intermediate film 14 also functions as a light-shielding film that prevents light from the outside that is incident on the semiconductor light emitting device 1 from reaching the semiconductor film 10.

A sealing resin body 15 made of, for example, an epoxy resin is provided below the intermediate film 14. The sealing resin body 15 covers the lower surface 10b and the end surface 10c of the semiconductor film 10, the portion of the passivation film 13 positioned lower than the upper surface 10a, the portion of the intermediate film 14 other than the end surface, the entire re-interconnect layer 11, and the side surface of the electrode 12.

On the other hand, a fluorescer film 16 made of a resin material in which a fluorescer (not shown) is dispersed is provided on the upper surface 10a of the semiconductor film 10. The fluorescer film 16 covers the upper surface 10a of the semiconductor film 10 and the portion of the passivation film 13 that is positioned higher than the upper surface 10a.

Thus, the intermediate film 14 is disposed between the passivation film 13 and the sealing resin body 15. When the internal stress of the sealing resin body 15 is used as a reference, the absolute value of the internal stress of the intermediate film 14 is less than the absolute value of the internal stress of the passivation film 13. In other words, the absolute value of the difference between the internal stress of the intermediate film 14 and the internal stress of the sealing resin body 15 is less than the absolute value of the difference between the internal stress of the passivation film 13 and the internal stress of the sealing resin body 15.

The absolute value of the difference between the internal stress of the sealing resin body 15 and the internal stress of the passivation film 13 or the intermediate film 14 (hereinbelow, also generally referred to as the target film) can be determined by Formula 1 recited below, where the parameters are defined as follows. The units are in parentheses.

Absolute value of the internal stress of the target film: |σn (Pa/K)|

Coefficient of thermal expansion of the target film: αn (1/K)

Coefficient of thermal expansion of the sealing resin body: α0 (1/K)

Young's modulus of the target film: En (Pa)

The Poisson's ratio of the target film: vn

$$\vert σ n \vert = \vert \frac{En \times ( α n - α 0 )}{1 - vn} \vert \qquad [ Formula 1 ]$$

As an example, the passivation film 13 is made of silicon oxide (SiO₂) having a thickness of 400 nm (nanometers). The intermediate film 14 is made of chrome, nickel, or titanium having a thickness of 100 nm. The sealing resin body 15 is made of, for example, an epoxy resin having a thickness of 1 mm (millimeter). The coefficient of thermal expansion α0 of the epoxy resin is 7×10⁻⁶ (1/K). Thereby, using the specific values of the parameters that are described below, the absolute value of the difference between the internal stress of the intermediate film 14 and the internal stress of the sealing resin body 15 is less than the absolute value of the difference between the internal stress of the passivation film 13 and the internal stress of the sealing resin body 15.

A method for manufacturing the semiconductor light emitting device according to the embodiment will now be described.

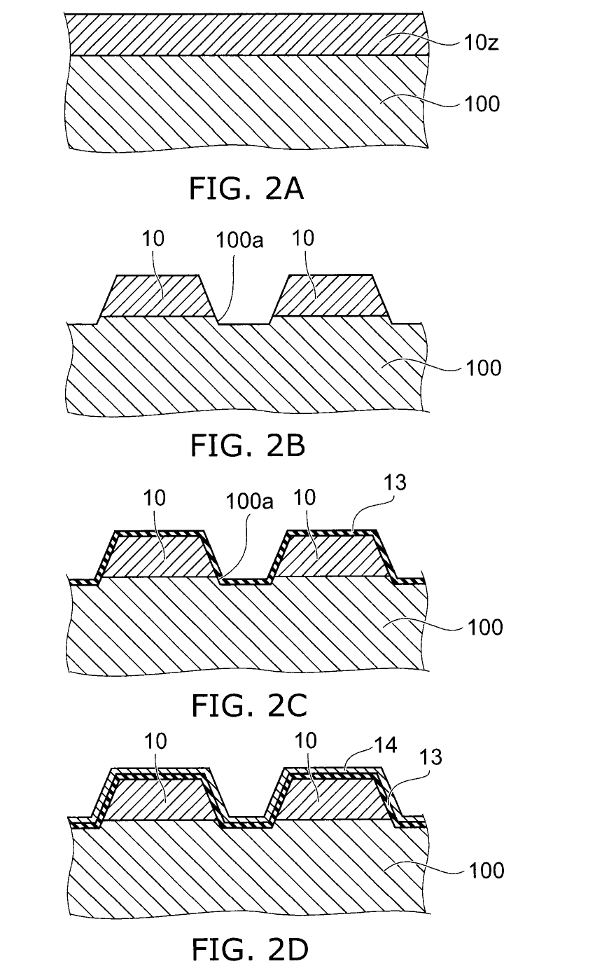

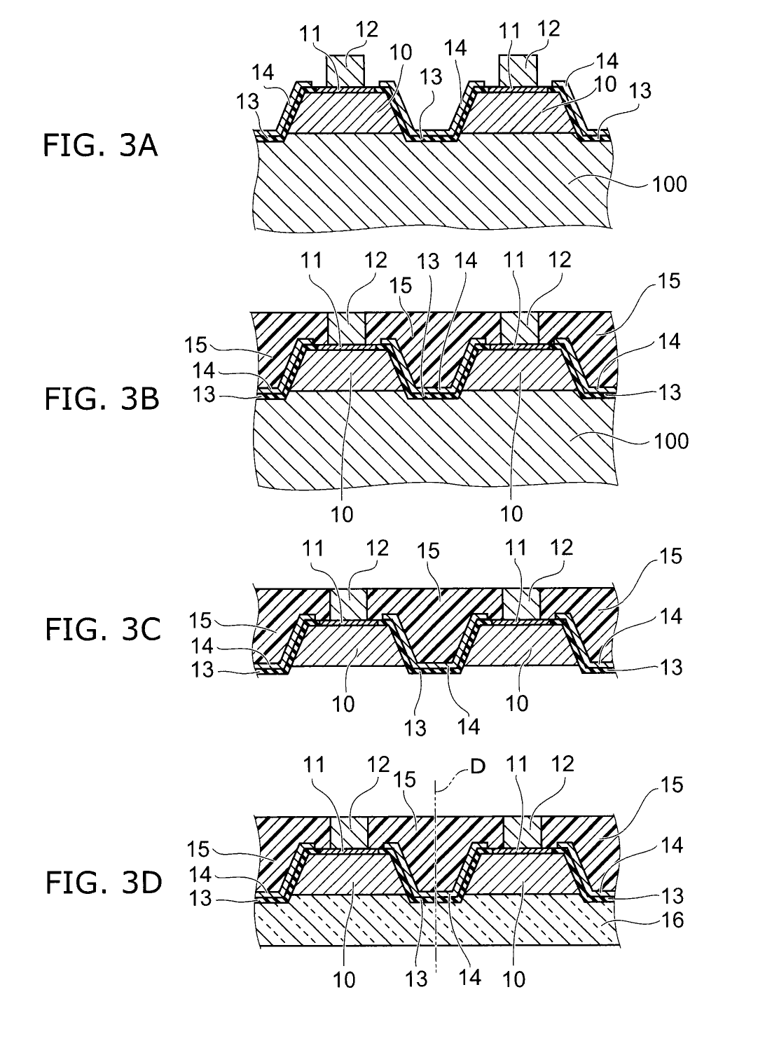

FIGS. 2A to 2D and FIGS. 3A to 3D are cross-sectional views of processes, showing the method for manufacturing the semiconductor light emitting device according to the embodiment.

For convenience of description, the vertical direction in FIGS. 2A to 2D and FIGS. 3A to 3D is reversed from the vertical direction in FIG. 1.

First, as shown in FIG. 2A, a silicon wafer 100 is prepared as the crystal growth substrate. Then, a semiconductor film 10z made of a Group III nitride semiconductor, e.g., gallium nitride (GaN), is grown as a crystal on the silicon wafer 100. The semiconductor film 10z is a continuous film. Also, electrode layers (not shown) are formed at the necessary regions on the semiconductor film 10z.

Then, as shown in FIG. 2B, the semiconductor film 10z is partitioned into the multiple semiconductor films 10 by selectively removing the semiconductor film 10z by etching. At this time, the etching is over-etched to dig into the region of the silicon wafer 100 between the semiconductor films 10 to make a trench 100a.

Continuing as shown in FIG. 2C, the passivation film 13 is formed by depositing silicon oxide onto the entire surface. Because the passivation film 13 is formed also inside the trench 100a, a portion of the passivation film 13 extends beyond the interface between the silicon wafer 100 and the semiconductor film 10 to the silicon wafer 100 side.

Then, as shown in FIG. 2D, the intermediate film 14 is formed by depositing, for example, a metal such as chrome (Cr) and nickel (Ni) or titanium (Ti), etc., onto the entire surface by vapor deposition, sputtering, etc.

Continuing as shown in FIG. 3A, the semiconductor film 10 is locally exposed by selectively removing the intermediate film 14 and the passivation film 13. Then, the re-interconnect layer 11 made of, for example, copper (Cu) is formed on the exposed portion of the semiconductor film 10. Continuing, the electrode 12 made of, for example, copper is formed on the re-interconnect layer 11. At this time, in the case where the intermediate film 14 is formed of a metal, the re-interconnect layer 11 and the electrode 12 are not formed in contact with the intermediate film 14. Although two sets of the set made of the re-interconnect layer 11 and the electrode 12 are formed on one semiconductor film 10, only one set is shown for convenience of illustration in FIGS. 3A to 3D.

Then, as shown in FIG. 3B, a resin material, e.g., an epoxy resin, is coated onto the silicon wafer 100 to cover the structures that are formed on the silicon wafer 100, i.e., the semiconductor film 10, the passivation film 13, the intermediate film 14, the re-interconnect layer 11, and the electrode 12. Continuing, the resin material and the passivation film 13 which is made of silicon oxide are baked by, for example, heating to a temperature of 160° C. Thereby, the resin material is cured to form the sealing resin body 15.

Continuing as shown in FIG. 3C, the silicon wafer 100 is removed. Thereby, the semiconductor film 10 and the passivation film 13 are exposed. The silicon wafer 100 is removed by a method such as polishing, wet etching using an alkaline solution, dry etching using an etching gas, etc. At this time, there are cases where the passivation film 13 is heated to about 100° C.

Then, as shown in FIG. 3D, a resin material in which a fluorescer is dispersed is coated onto the exposed surface of the semiconductor film 10 and the passivation film 13 and is baked. The baking temperature is, for example, 170° C. Thereby, the fluorescer film 16 is formed.

Continuing, dicing of the structural body made of the fluorescer film 16, the semiconductor film 10, the sealing resin body 15, etc., is performed along a dicing line D. Thereby, the structural body is singulated into each of the semiconductor films 10; and the semiconductor light emitting device 1 shown in FIG. 1 is manufactured.

Effects of the embodiment will now be described.

In the embodiment, the intermediate film 14 is provided between the passivation film 13 and the sealing resin body 15. The absolute value of the difference between the internal stress of the intermediate film 14 and the internal stress of the sealing resin body 15 is less than the absolute value of the difference between the internal stress of the passivation film 13 and the internal stress of the sealing resin body 15. Therefore, the intermediate film 14 functions as a stress relieving film between the passivation film 13 and the sealing resin body 15; and cracks due to the stress applied from the sealing resin body 15 can be prevented from occurring in the passivation film 13.

For example, in the semiconductor light emitting device 1 after completion, the mechanical reliability can be ensured over a long period of time even when thermal stress occurs in the interior of the semiconductor light emitting device 1 when repeatedly turning on and off.

Also, damage of the passivation film 13 can be prevented even when subjected to thermal stress in the manufacturing processes of the semiconductor light emitting device 1. For example, cracks can be prevented from occurring in the passivation film 13 in the heat treatment process for baking the fluorescer film 16. In the process of removing the silicon wafer 100, damage of the passivation film 13 by the thermal stress due to the heating can be suppressed even if the passivation film 13 and the sealing resin body 15 are heated.

Moreover, in the semiconductor light emitting device 1 according to the embodiment, the light extraction efficiency is high because the intermediate film 14 functions as a reflective film and a light-shielding film. Further, the intermediate film 14 extends to a height in the vicinity of the upper surface 10a of the semiconductor film 10 because the passivation film 13 extends to a position that is higher than the upper surface 10a of the semiconductor film 10. Therefore, the stress relieving effect and the effects of reflecting and optically shielding described above can be increased further.

Although an example is illustrated in the embodiment in which a silicon wafer is used as the crystal growth substrate, this is not limited thereto; and, for example, a sapphire substrate, a SiC substrate, or a ZnO substrate may be used. Although the intermediate film 14 is formed as the reflecting and light-shielding film in the embodiment, this is not limited thereto.

A second embodiment will now be described.

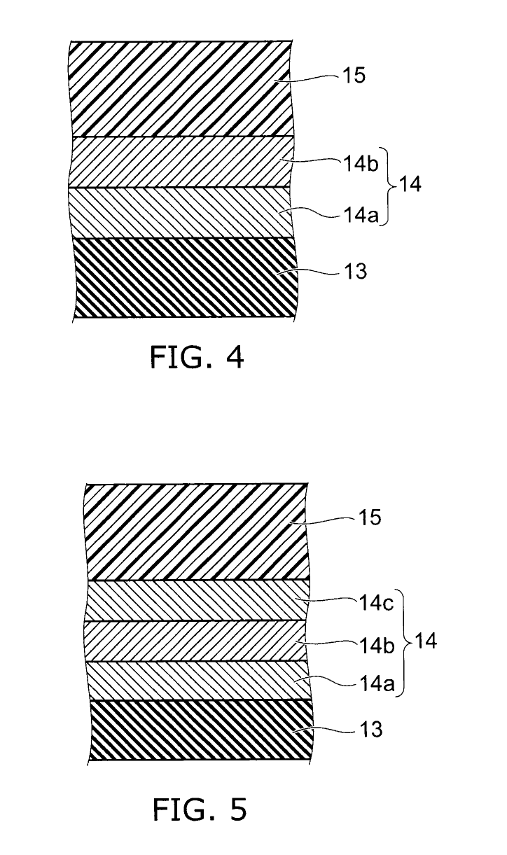

FIG. 4 is a cross-sectional view showing the intermediate film of a semiconductor light emitting device according to the embodiment.

In the embodiment as shown in FIG. 4, the intermediate film 14 is a two-layer film in which the two layers of partial layers 14a and 14b are stacked in this order from the passivation film 13 toward the sealing resin body 15.

Then, when the internal stress of the sealing resin body 15 is used as a reference, the internal stress changes in one direction for the passivation film 13, the partial layer 14a, and the partial layer 14b.

In other words, Formula 2 recited below holds, where the absolute value of the difference between the internal stress of the passivation film 13 and the internal stress of the sealing resin body 15 is |σ₁₃|, the absolute value of the difference between the internal stress of the partial layer 14a and the internal stress of the sealing resin body 15 is |σ₁₄ₐ|, and the absolute value of the difference between the internal stress of the partial layer 14b and the internal stress of the sealing resin body 15 is |σ_{14b}|. The internal stress of each of the layers can be determined by Formula 1 recited above.

|σ₁₃|>|σ₁₄ₐ|>|σ_{14b}| [Formula 2]

As an example, similarly to the first embodiment described above, the passivation film 13 is made of silicon oxide (SiO₂) having a thickness of 400 nm. The sealing resin body 15 is made of an epoxy resin having a thickness of 1 mm (millimeter). The partial layer 14a is made of nickel (Ni) having a thickness of 100 nm. The partial layer 14b is made of chrome (Cr) having a thickness of 100 nm. In other words, the film configuration from the passivation film 13 to the sealing resin body 15 can be notated as SiO₂/Ni/Cr/epoxy resin. Thereby, using the specific values of the parameters that are described below, Formula 2 recited above is satisfied.

According to the embodiment, the intermediate film 14 is a two-layer film; and the stress relieving effect can be increased even more by changing the internal stress difference with respect to the sealing resin body in stages. Otherwise, the configuration, the manufacturing method, and the effects of the embodiment are similar to those of the first embodiment described above.

A third embodiment will now be described.

FIG. 5 is a cross-sectional view showing the intermediate film of a semiconductor light emitting device according to the embodiment.

In the embodiment as shown in FIG. 5, the intermediate film 14 is a three-layer film in which the three layers of the partial layers 14a, 14b, and 14c are stacked in this order from the passivation film 13 toward the sealing resin body 15.

When the internal stress of the sealing resin body 15 is used as a reference, the internal stress changes in one direction for the passivation film 13, the partial layer 14a, the partial layer 14b, and the partial layer 14c.

In other words, Formula 3 recited below holds, where the absolute value of the difference between the internal stress of the passivation film 13 and the internal stress of the sealing resin body 15 is |σ₁₃|, the absolute value of the difference between the internal stress of the partial layer 14a and the internal stress of the sealing resin body 15 is |σ₁₄ₐ|, the absolute value of the difference between the internal stress of the partial layer 14b and the internal stress of the sealing resin body 15 is |σ_{14b}|, and the absolute value of the difference between the internal stress of the partial layer 14c and the internal stress of the sealing resin body 15 is |σ_{14c}|. The internal stress of each of the layers can be determined by Formula 1 recited above.

|σ₁₃|>|σ₁₄ₐ|>|σ_{14b}|>|σ_{14c}| [Formula 3]

As an example, similarly to the second embodiment described above, the passivation film 13 is made of silicon oxide (SiO₂) having a thickness of 400 nm. The sealing resin body 15 is made of an epoxy resin having a thickness of 1 mm. The partial layer 14a is made of nickel (Ni) having a thickness of 100 nm. The partial layer 14b is made of chrome (Cr) having a thickness of 100 nm. The partial layer 14c is made of titanium (Ti) having a thickness of 100 nm. In other words, the film configuration from the passivation film 13 to the sealing resin body 15 can be notated as SiO₂/Ni/Cr/Ti/epoxy resin. Thereby, using the specific values of the parameters that are described below, Formula 3 recited above is satisfied.

According to the embodiment, the intermediate film 14 is a three-layer film; and the stress relieving effect can be higher than that of the second embodiment by changing the internal stress difference with respect to the sealing resin body in stages. Otherwise, the configuration, the manufacturing method, and the effects of the embodiment are similar to those of the second embodiment described above.

Although examples are illustrated in the second and third embodiments described above in which the intermediate film 14 is a two-layer film and a three-layer film, respectively, this is not limited thereto; and the intermediate film 14 may be a film of four or more layers. In such a case, the relationship between the partial layers generally can be expressed as follows.

Namely, the absolute value of the difference between the internal stress of the sealing resin body 15 and the internal stress of the partial layer of the multiple partial layers included in the intermediate film that is disposed to be most proximal to the passivation film 13 side is less than the absolute value of the difference between the internal stress of the passivation film 13 and the internal stress of the sealing resin body 15; and the absolute value of the difference between the internal stress of the sealing resin body 15 and the internal stress of the partial layer disposed relatively on the sealing resin body 15 side is less than the absolute value of the difference between the internal stress of the sealing resin body 15 and the internal stress of the partial layer disposed relatively on the passivation film 13 side.

However, in the case where a layer having a thickness exceeding the critical film thickness is included as a partial layer, the internal stress difference with respect to the sealing resin body is changed in stages without considering this layer. Generally, a layer in which internal stress occurs will not break when thinner than a constant film thickness and will break when thicker than the constant film thickness; and the upper limit of the film thickness range within which the film does not break is called the critical film thickness. In the case where a partial layer having a thickness exceeding the critical film thickness is included in the intermediate film, the relationship between the stacking order and the order of the internal stress described above is not applicable to this partial layer because this partial layer breaks and its internal stress is relieved.

An example of the embodiment will now be described.

A semiconductor light emitting device was actually made by the method described in the first embodiment described above; and it was evaluated whether or not cracks occurred in the passivation film 13 in the manufacturing processes. Six types of samples (1) to (6) recited below were evaluated. However, in all of the samples, the passivation film 13 was a film made of silicon oxide (SiO₂) having a thickness of 400 nm; and the sealing resin body 15 was a film made of an epoxy resin having a thickness of 1 mm. In other words, in samples (1) to (6) recited below, “SiO₂ (400 nm)” is the passivation film 13; and “epoxy resin (1 mm)” is the sealing resin body 15.

SiO₂ (400 nm)/Cr (100 nm)/epoxy resin (1 mm) (1) First Example

SiO₂ (400 nm)/Ni (100 nm)/epoxy resin (1 mm) (2) Second Example

SiO₂ (400 nm)/Ti (100 nm)/epoxy resin (1 mm) (3) Third Example

SiO₂ (400 nm)/Ni (100 nm)/Cr (100 nm)/epoxy resin (1 mm) nm)/epoxy resin (1 mm) (4) Fourth Example

SiO₂ (400 nm)/Ni (100 nm)/Cr (100 nm)/Ti (100 nm)/epoxy resin (1 mm) (5) Fifth Example

SiO₂ (400 nm)/(no intermediate film)/epoxy resin (1 mm) (6) First Comparative Example

Properties of the materials and the internal stress calculated by Formula 1 recited above are shown in Table 1.

TABLE 1

| | | | Coefficient | |
|---|---|---|---|---|
| | Poisson's | | of thermal | |
| | ratio | Young's | expansion | Stress σ(T) |
| Material | (GPa) | modulus | 10⁻⁶(1/K) | (Pa/K) |
| SiO₂ | 0.230 | 76.5 | 0.5 | 646 |
| Ni | 0.306 | 207 | 5.3 | 507 |
| Cr | 0.343 | 110 | 4.9 | 352 |
| Ti | 0.321 | 111.6 | 8.6 | 263 |

As a result of the experiments, breakage was not confirmed in the passivation film 13 of the first to fifth examples. Conversely, in the first comparative example, cracks occurred in the passivation film 13 in the heat treatment for baking the fluorescer film 16.

According to the embodiments described above, a semiconductor light emitting device having high reliability can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor light emitting device, comprising:
a semiconductor film containing a Group III nitride semiconductor;
an electrode connected to a first surface of the semiconductor film;
a passivation film covering an end surface of the semiconductor film and a region of the first surface other than a region contacting the electrode;
a sealing resin body covering the first surface of the semiconductor film and a side surface of the electrode to leave a second surface of the semiconductor film exposed; and
an intermediate film provided between the passivation film and the sealing resin body,
the absolute value of the difference between an internal stress of the intermediate film and an internal stress of the sealing resin body being less than the absolute value of the difference between an internal stress of the passivation film and the internal stress of the sealing resin body.

2. The device according to claim 1, wherein
the intermediate film includes a plurality of partial layers stacked from the passivation film toward the sealing resin body,
the absolute value of the difference between the internal stress of the sealing resin body and an internal stress of the partial layer of the plurality of partial layers disposed to be most proximal to the passivation film is less than the absolute value of the difference between the internal stress of the passivation film and the internal stress of the sealing resin body, and
the absolute value of the difference between the internal stress of the sealing resin body and an internal stress of the partial layer of the plurality of partial layers disposed relatively on the sealing resin body side is less than the absolute value of the difference between the internal stress of the sealing resin body and an internal stress of the partial layer of the plurality of partial layers disposed relatively on the passivation film side.

3. The device according to claim 1, wherein the passivation film extends along the end surface of the semiconductor film to a position beyond the second surface.

4. The device according to claim 1, wherein the intermediate film is made of a metal and is not disposed in contact with the electrode.

5. The device according to claim 4, wherein the intermediate film contains at least one metal selected from the group consisting of chrome, nickel, and titanium.

6. The device according to claim 1, wherein the passivation film contains silicon oxide, and the sealing resin body contains an epoxy resin.

7. The device according to claim 1, further comprising a fluorescer film covering the second surface.

8. A semiconductor light emitting device, comprising:
a semiconductor film containing a Group III nitride semiconductor;
an electrode connected to a first surface of the semiconductor film;
a passivation film covering an end surface of the semiconductor film and a region of the first surface other than a region contacting the electrode;
a sealing resin body covering the first surface of the semiconductor film and a side surface of the electrode to leave a second surface of the semiconductor film exposed; and
an intermediate film provided between the passivation film and the sealing resin body,
the intermediate film including:
a first partial layer disposed relatively on the passivation film side; and
a second partial layer disposed relatively on the sealing resin body side,
the absolute value of the difference between an internal stress of the first partial layer and an internal stress of the sealing resin body being less than the absolute value of the difference between an internal stress of the passivation film and the internal stress of the sealing resin body, and
the absolute value of the difference between an internal stress of the second partial layer and the internal stress of the sealing resin body being less than the absolute value of the difference between the internal stress of the first partial layer and the internal stress of the sealing resin body.

9. The device according to claim 8, wherein
the passivation film is made of silicon oxide,
the first partial layer is made of nickel,
the second partial layer is made of chrome, and
the sealing resin body is made of an epoxy resin.

10. A semiconductor light emitting device, comprising:
a semiconductor film containing a Group III nitride semiconductor;
an electrode connected to a first surface of the semiconductor film;
a passivation film covering an end surface of the semiconductor film and a region of the first surface other than a region contacting the electrode;
a sealing resin body covering the first surface of the semiconductor film and a side surface of the electrode to leave a second surface of the semiconductor film exposed; and
an intermediate film provided between the passivation film and the sealing resin body,
the intermediate film including:
a first partial layer disposed relatively on the passivation film side;
a third partial layer disposed relatively on the sealing resin body side; and
a second partial layer disposed between the first partial layer and the third partial layer,
the absolute value of the difference between an internal stress of the first partial layer and an internal stress of the sealing resin body being less than the absolute value of the difference between an internal stress of the passivation film and the internal stress of the sealing resin body,
the absolute value of the difference between an internal stress of the second partial layer and the internal stress of the sealing resin body being less than the absolute value of the difference between the internal stress of the first partial layer and the internal stress of the sealing resin body, and
the absolute value of the difference between an internal stress of the third partial layer and the internal stress of the sealing resin body being less than the absolute value of the difference between the internal stress of the second partial layer and the internal stress of the sealing resin body.

11. The device according to claim 10, wherein
the passivation film is made of silicon oxide,
the first partial layer is made of nickel,
the second partial layer is made of chrome,
the third partial layer is made of titanium, and
the sealing resin body is made of an epoxy resin.
